(19) United States
(12) Patent Application Publication
(10) Pub. No.: US 2011/0234710 A1
(43) Pub. Date: Sep. 29, 2011

(54) LIQUID EJECTING HEAD, METHOD FOR MANUFACTURING THE SAME AND LIQUID EJECTING APPARATUS

(75) Inventors: Seiichi Fujita, Shiojiri-shi (JP); Shiro Yazaki, Chino-shi (JP)

(73) Assignee: SEIKO EPSON CORPORATION, Shinjuku-ku (JP)

(21) Appl. No.: 13/071,435

(22) Filed: Mar. 24, 2011

(30) Foreign Application Priority Data
Mar. 26, 2010 (JP) 2010-073836

(51) Int. Cl. B41J 2/045; H01L 41/22

(52) U.S. Cl. 347/70; 29/25.35

(57) ABSTRACT

There is provided a liquid ejecting head in which a surface layer of a vibration plate at the side of a flow path formation substrate is formed by an insulating film made of zirconium oxide and a protection film made of a material which is resistant to liquid is provided on a surface of the flow path formation substrate so as to cover wall surfaces of liquid flow paths.

This application claims a priority to Japanese Patent Application No. 2010-073836 filed on Mar. 26, 2010 which is hereby expressly incorporated by reference herein in its entirety.

### BACKGROUND

1. Technical Field

The present invention relates to a liquid ejecting head which deforms a vibration plate constituting one side surfaces of pressure generation chambers with piezoelectric elements so as to eject liquid droplets through nozzles with pressure change caused in the pressure generation chambers at the time of the deformation, a method for manufacturing the liquid ejecting head and a liquid ejecting apparatus.

2. Related Art

An ink jet recording head which ejects ink droplets through nozzles is exemplified as a representative example of a liquid ejecting head. Various configurations of the ink jet recording head have been proposed. For example, there is an ink jet recording head which includes a flow path formation substrate, a vibration plate and piezoelectric elements (for example, see JP-A-2004-262225). The flow path formation substrate is formed with a silicon substrate and liquid flow paths including pressure generation chambers communicating with nozzles are formed on the flow path formation substrate. The vibration plate is provided at one surface side of the flow path formation substrate. The piezoelectric elements are provided on the vibration plate.

In the ink jet recording head having such configuration, most part of wall surfaces of liquid flow paths such as pressure generation chambers is formed with silicon oxide. The silicon oxide is a material which is relatively hard to be corroded away by ink but is gradually corroded away when used for a long period of time. Therefore, shapes of the pressure generation chambers are gradually changed. Further, a shape (thickness) of the vibration plate is gradually changed so that a displacement amount thereof is changed. Accordingly, there arises a risk that an ejection characteristic of ink droplets is gradually changed when used for a long period of time.

For example, in order to solve the above problem, in the configuration described in JP-A-2004-262225, a protection film is provided on the wall surfaces of the flow paths such as pressure generation chambers. This makes it possible to suppress a flow path formation substrate constituting the flow paths such as the pressure generation chambers, a vibration plate, and the like from being corroded away by ink at some degree.

However, there is a portion where a protection film is hard to be deposited, such as a boundary portion between the flow path formation substrate and the vibration plate. In such a case, there arises a risk that the vibration plate and the like is not sufficiently suppressed from being corroded away by ink. Further, there is a risk that a displacement characteristic of the vibration plate is changed by the protection film and variation happens easily on an ejection characteristic of ink droplets of each head.

It is to be noted that such problem is caused to happen not only on the ink jet recording head which ejects ink droplets but on other liquid ejecting heads which ejects liquid droplets other than ink, of course.

### SUMMARY

An advantage of some aspects of the invention is to provide a liquid ejecting head which can suppress a wall surface of a liquid flow path from being corroded away by liquid and desirably maintain an ejection characteristic of liquid droplets for a long period of time, a method for manufacturing the liquid ejecting head and a liquid ejecting apparatus.

According to an aspect of the invention, there is a liquid ejecting head which includes a flow path formation substrate on which liquid flow paths including nozzles for ejecting liquid droplets and pressure generation chambers communicating with the nozzles are formed, a vibration plate which is provided on the flow path formation substrate and constitutes one side surfaces of the pressure generation chambers, and piezoelectric elements which are provided on the vibration plate and each of which corresponds to each of the pressure generation chambers. In the liquid ejecting head, an surface layer of the vibration plate at the side of the flow path formation substrate is formed by an insulating film made of zirconium oxide, and a protection film made of a material which is resistant to liquid is provided on a surface of the flow path formation substrate so as to cover wall surfaces of the liquid flow paths.

According to the aspect of the invention, since liquid flow paths are constituted by an insulating film made of zirconium oxide and a protection film, wall surfaces of the liquid flow paths are effectively suppressed from being corroded away by liquid. Accordingly, an ejection characteristic of liquid droplets can be desirably maintained for a long period of time.

It is preferable that the protection film be made of tantalum oxide. This makes it possible to reliably suppress the wall surfaces of the liquid flow paths from being corroded away by liquid.

It is preferable that the flow path formation substrate be made of a silicon substrate. Therefore, the liquid flow paths such as the pressure generation chambers are formed with high accuracy, thereby improving an ejection characteristic. Further, an excellent ejection characteristic at an initial state can be desirably maintained for a long period of time.

Further, according to another aspect of the invention, there is provided a liquid ejecting apparatus including the above liquid ejecting head. Using the above liquid ejecting apparatus, a liquid ejecting apparatus of which durability is improved can be realized.

Further, according to still another aspect of the invention, there is provided a method for manufacturing a liquid ejecting head which includes a flow path formation substrate on which liquid flow paths including nozzles for ejecting liquid droplets and pressure generation chambers communicating with the nozzles are formed, a vibration plate which is provided on the flow path formation substrate and constitutes one side surfaces of the pressure generation chambers, and piezoelectric elements which are provided on the vibration plate and each of which corresponds to each of the pressure generation chambers, the method including; forming a protection film made of a material which is resistant to liquid on a surface of the flow path formation substrate on which the liquid flow paths are formed so as to cover wall surfaces of the liquid flow paths, forming an oxide film made of silicon dioxide by thermally oxidizing a surface of a supporting substrate made of a silicon substrate, forming the vibration plate including at least an insulating film made of zirconium oxide on the oxide film, forming the piezoelectric elements on the vibration plate, exposing a surface of the insulating film by removing the supporting substrate and the oxide film from a surface opposite to the piezoelectric elements, and bonding the insulating film constituting the vibration plate and the flow path formation substrate on which the protection film is formed to each other.

According to the aspect of the invention, an ink jet recording head in which wall surfaces of liquid flow paths on a flow path formation substrate is constituted by an insulating film made of zirconium oxide and a protection film can be desirably manufactured.

### BRIEF DESCRIPTION OF THE DRAWINGS

The invention will be described with reference to the accompanying drawings, wherein like numbers reference like elements.

FIG. 1 is an exploded perspective view illustrating a recording head according to an embodiment of the invention.

FIGS. 2A and 2B are a plan view and a cross-sectional view illustrating the recording head according to an embodiment of the invention.

FIGS. 3A and 3B are cross-sectional views illustrating a manufacturing process of the recording head according to an embodiment of the invention.

FIGS. 4A to 4C are cross-sectional views illustrating a manufacturing process of the recording head according to an embodiment of the invention.

FIGS. 5A to 5C are cross-sectional views illustrating a manufacturing process of the recording head according to an embodiment of the invention.

FIG. 6 is a view illustrating a schematic configuration of a recording apparatus according to an embodiment of the invention.

### DESCRIPTION OF EXEMPLARY EMBODIMENTS

Hereinafter, the invention is described in detail with reference to an embodiment.

### First Embodiment

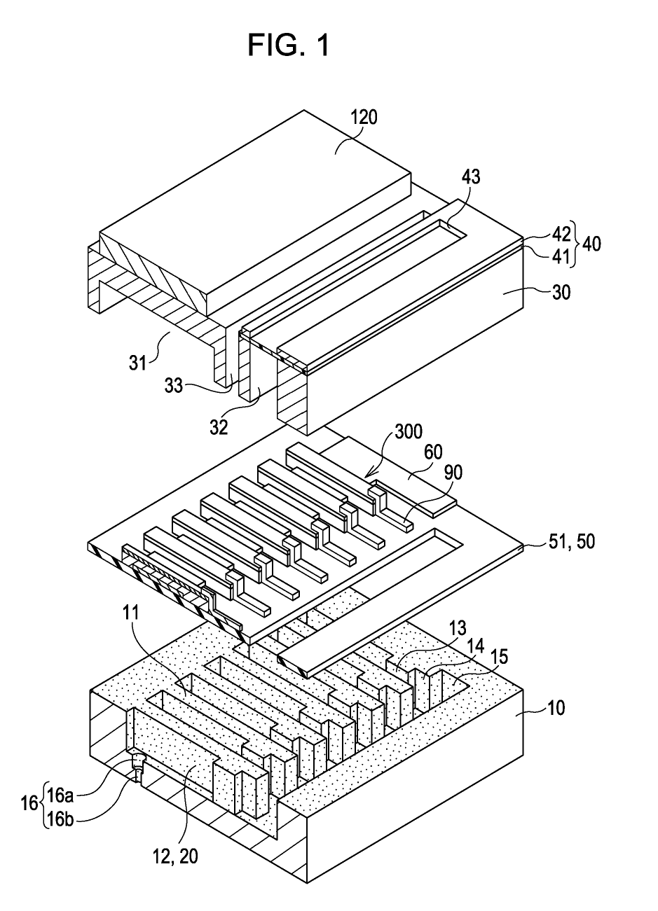

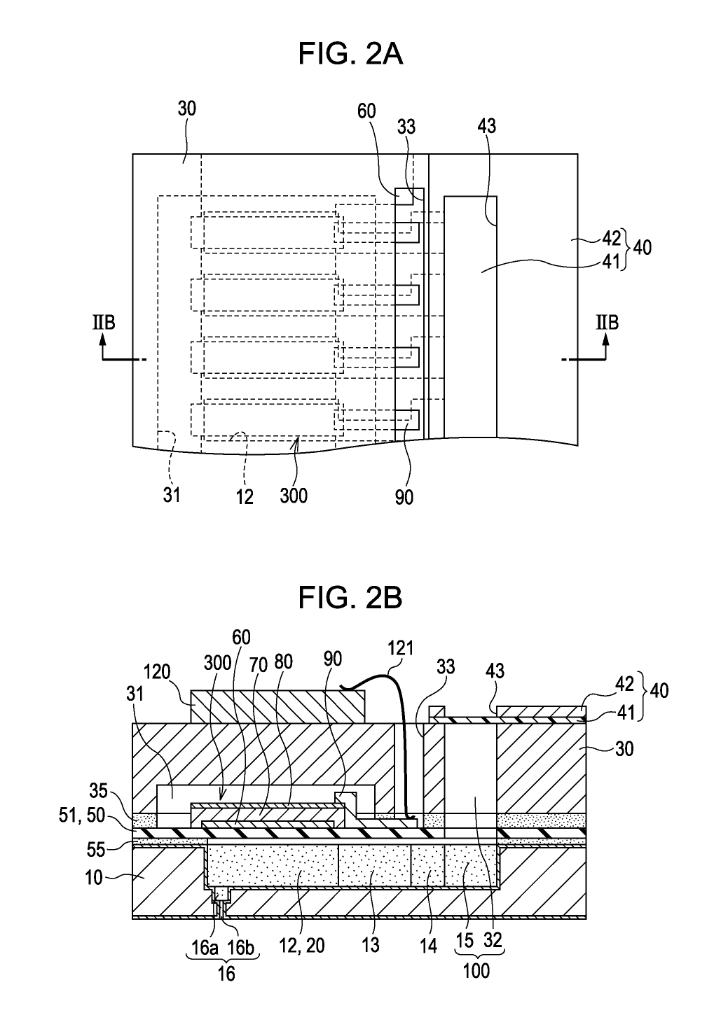

FIG. 1 is an exploded perspective view illustrating an ink jet recording head as an example of a liquid ejecting head according to the first embodiment of the invention. FIGS. 2A and 2B are a plan view and a cross-sectional view of FIG. 1, respectively.

As shown in FIG. 1 and FIGS. 2A and 2B, a plurality of pressure generation chambers 12 are arranged in parallel on a flow path formation substrate 10 constituting an ink jet recording head in a width direction thereof. The plurality of pressure generation chambers 12 are partitioned by separation walls 11. Further, ink supply paths 13 and communicating paths 14 are provided at the side of one ends of the pressure generation chambers 12 in a longitudinal direction on the flow path formation substrate 10. The ink supply paths 13 and the communicating paths 14 are partitioned by the separation walls 11 and communicate with the pressure generation chambers 12. Further, a communicating portion 15 is provided at an outer side of the communicating paths 14. The communicating portion 15 communicates with each of the communicating paths 14.

It is to be noted that although a material of the flow path formation substrate 10 is not particularly limited, a silicon single crystal substrate having a crystal plane orientation (110) or the like is preferably used, for example. Further, the pressure generation chambers 12, the ink supply paths 13, the communicating paths 14, and the communicating portion 15 are formed so as not to penetrate through the flow path formation substrate 10 in the thickness direction by dry etching, for example, from one surface side thereof although described in detail later.

Nozzles 16 are arranged in a row on the flow path formation substrate 10. The nozzles 16 are opened at the other surface side of the flow path formation substrate 10 and each of the nozzles 16 communicates with each of the pressure generation chambers 12. Although shapes of the nozzles 16 are not particularly limited, each nozzle 16 according to the embodiment is constituted by a large diameter portion 16a and a small diameter portion 16b having an inner diameter which is smaller than that of the large diameter portion 16a, for example. The large diameter portion 16a is provided at the side of the pressure generation chambers 12. The small diameter portion 16b is provided at the side where ink droplets are discharged.

In such a manner, ink flow paths (liquid flow paths) including the pressure generation chambers 12, the ink supply paths 13, the communicating paths 14, the communicating portion 15 and the nozzles 16 are integrally formed on the flow path formation substrate 10. Further, a protection film 20 is formed on wall surfaces of the ink flow paths such as the pressure generation chambers 12. The protection film 20 is made of a material which is resistant to ink, for example, tantalum oxide or the like. In the embodiment, the protection film 20 is formed on the entire surface of the flow path formation substrate 10 including the wall surfaces of the ink flow paths such as the pressure generation chambers 12.

It is to be noted that each ink supply path 13 is formed so as to have a cross section narrower than that of each pressure generation chamber 12 and keeps a flow path resistance to ink flowing into each pressure generation chamber 12 from the communicating portion 15 to be constant. The communicating paths 14 are formed by the separation walls 11 formed at both sides in the width direction of the pressure generation chambers 12 so as to extend to the side of the communicating portion 15 and defining spaces between the ink supply paths 13 and the communicating portion 15. The communicating portion 15 communicates with a reservoir portion 32 of a protection substrate 30 so as to constitute a reservoir 100, which will be described later.

The vibration plate 50 is bonded to a surface of the flow path formation substrate 10 at an opposite side of the nozzles 16 with an adhesive 55, for example. Note that the vibration plate 50 includes an insulating film 51 made of zirconium oxide. The insulating film 51 constitutes an surface layer at the side of the flow path formation substrate 10. For example, in the embodiment, the insulating film 51 is formed to have a thickness of substantially 1.0 through 1.2 μm. The vibration plate 50 is formed by only the insulating film 51.

Therefore, one side surfaces of the pressure generation chambers 12, the ink supply paths 13 and the communicating paths 14 formed on the flow path formation substrate 10 are formed by the insulating film 51. That is, in the invention, the wall surfaces of the ink flow paths such as the pressure generation chambers 12 formed on the flow path formation substrate 10 are formed by the insulating film 51, which constitutes the vibration plate 50 and is made of zirconium oxide, and the protection film 20, which is formed on the surface of the flow path formation substrate 10 and is made of tantalum oxide.

This makes it possible to effectively suppress the wall surfaces of the ink flow paths formed on the flow path formation substrate 10 from being corroded away by ink. That is to say, change of an ejection characteristic of ink droplets caused when the wall surfaces of the ink flow paths are corroded away can be suppressed to be significantly small. Accordingly, the ejection characteristic of ink droplets can be desirably maintained for a long period of time. An etching rate of zirconium oxide or tantalum oxide by ink is equal to or lower than one tenth of an etching rate of silicon dioxide, for example. Therefore, the ejection characteristic of ink droplets do not largely change when used for a long period of time since the wall surfaces of the ink flow paths such as the pressure generation chambers 12 are formed by the insulating film 51 and the protection film 20. Further, since the vibration plate 50 is formed by only the insulating film 51, there is an effect that variation of a displacement amount of the vibration plate 50 is made small in comparison with a case where the vibration plate 50 is formed by a plurality of layers.

It is to be noted that piezoelectric elements 300 are formed on the insulating film 51 constituting the vibration plate 50. The piezoelectric elements 300 are formed by a lower electrode 60, piezoelectric layers 70, and upper electrodes 80. In addition, a lead electrode 90 is connected to each upper electrode 80 of each piezoelectric element 300. Each upper electrode 80 and a driving IC which will be described later are connected to each other through the lead electrode 90.

In the embodiment, the insulating film 51 constitutes the vibration plate 50. However, the lower electrode 60 may also serve as the vibration plate 50 together with the insulating film 51. In any cases, it is sufficient that the vibration plate 50 is formed such that the surface layer at the side of the pressure generation chambers 12 is formed by the insulating film 51, in addition, the vibration plate 50 may include other layers.

The protection substrate 30 is bonded to a surface of the flow path formation substrate 10 at the side of the piezoelectric elements 300 with an adhesive 35, for example. The protection substrate 30 has a piezoelectric element holding portion 31 for protecting the piezoelectric elements 300. The reservoir portion 32 is provided on the protection substrate 30 in addition to the piezoelectric element holding portion 31. The reservoir portion 32 communicates with the communicating portion 15 formed on the flow path formation substrate 10 as described above so as to constitute the reservoir 100.

A material of the protection substrate 30 is not particularly limited. However, a material which has substantially the same coefficient of thermal expansion as that of the flow path formation substrate 10, for example, a glass material, a ceramic material or the like is preferably used as the material of the protection substrate 30. In the embodiment, a silicon substrate which is the same material as the flow path formation substrate 10 is used.

Further, a through-hole 33 is provided on the protection substrate 30. The through-hole 33 penetrates through the protection substrate 30 in the thickness direction. Portions in the vicinity of ends of the lead electrodes 90 drawn from the piezoelectric elements 300 are exposed within the through-hole 33. A driving IC 120 for driving the piezoelectric elements 300 arranged in parallel is fixed onto the protection substrate 30. In addition, the driving IC 120 and the lead electrodes 90 are electrically connected to each other with connection wirings 121. Each connection wiring 121 is formed with a conductive wire such as a bonding wire extended within the through-hole 33.

A compliance substrate 40 formed by a sealing film 41 and a fixing plate 42 is bonded onto the protection substrate 30. The sealing film 41 is made of a material having flexibility and low rigidity. One surface of the reservoir portion 32 is sealed with the sealing film 41. Further, the fixing plate 42 is made of a hard material such as a metal. A region of the fixing plate 42 opposed to the reservoir 100 serves as an opening 43 where the fixing plate 42 is completely removed in the thickness direction. Therefore, one surface of the reservoir 100 is sealed with only the sealing film 41 having flexibility.

In the ink jet recording head according to the embodiment having such configuration, ink is taken from an external ink supply unit (not shown) to fill an inner portion from the reservoir 100 to the nozzles 16. Thereafter, in accordance with a recording signal from the driving IC 120, a voltage is applied to each piezoelectric element 300 corresponding to each pressure generation chamber 12 so as to deform each piezoelectric element 300 in a flexural deformation manner. This increases pressure in each pressure generation chamber 12 so that ink droplets are ejected through each nozzle 16.

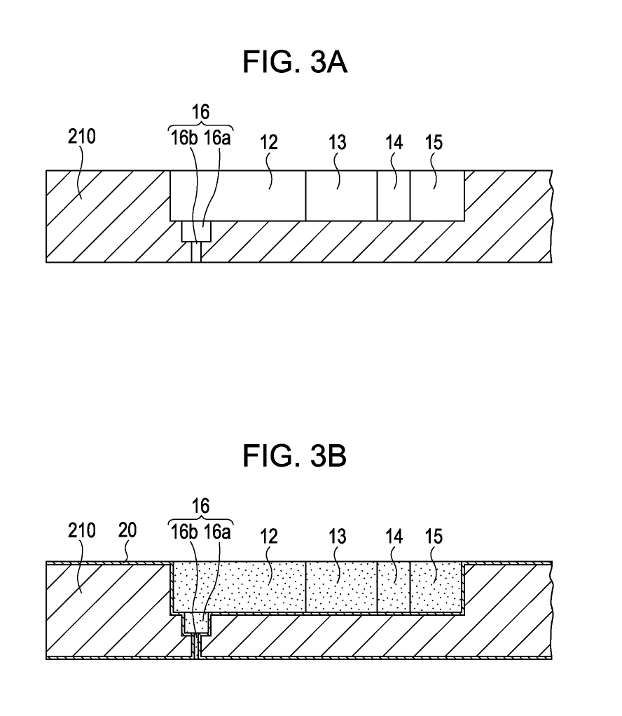

Hereinafter, a manufacturing process of the ink jet recording head according to the embodiment is described. It is to be noted that FIG. 3A through FIG. 5C are cross-sectional views of each member in a longitudinal direction of the pressure generation chambers.

At first, as shown in FIG. 3A, for example, a flow path formation substrate wafer 210 is dry-etched to form the pressure generation chambers 12, the ink supply paths 13, the communicating paths 14, the communicating portion 15 and the nozzles 16, which are ink flow paths. The flow path formation substrate wafer 210 is a silicon wafer on which a plurality of flow path formation substrates 10 are integrally formed. Since it is sufficient that these ink flow paths are formed by using a commonly known technique, methods for forming the ink flow paths are not described in detail.

Next, as shown in FIG. 3B, the protection film 20 made of tantalum oxide is formed on a surface of the flow path formation substrate wafer 210 including the wall surfaces of the ink flow paths such as the pressure generation chambers 12 by a CVD method or the like, for example.

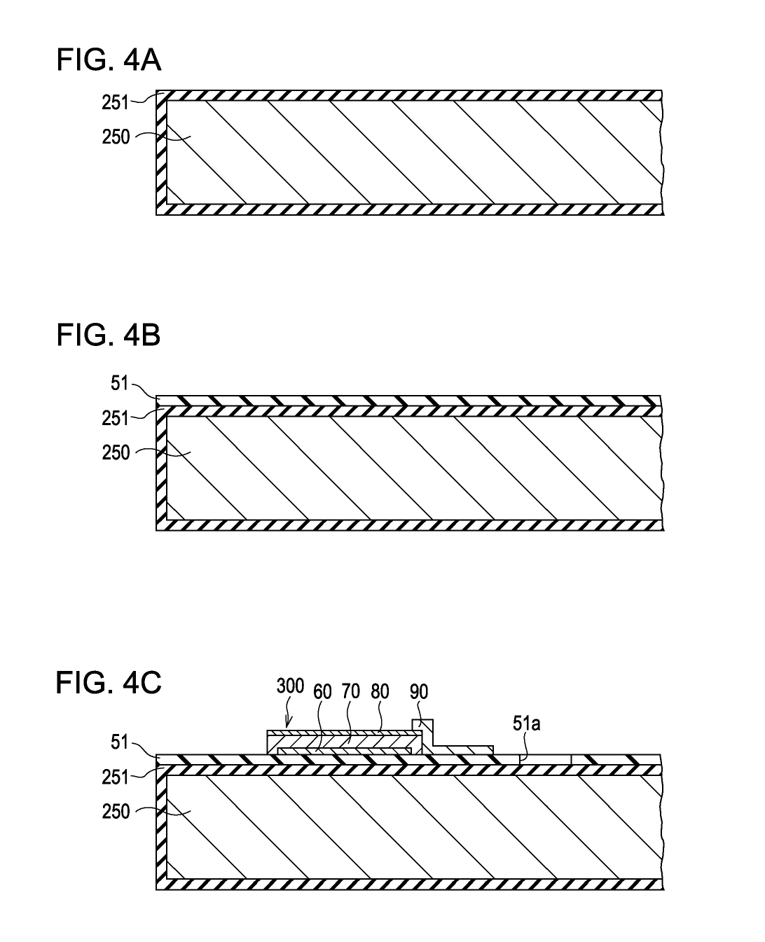

On the other hand, as shown in FIG. 4A, an oxide film 251 is formed on the surface of a supporting substrate 250 formed by a silicon wafer. To be more specific, the supporting substrate 250 is thermally oxidized in a diffusion furnace at substantially 1100° C. so as to form the oxide film 251 made of silicon dioxide on the surface of the supporting substrate 250. For example, the supporting substrate 250 is formed to have a thickness of substantially 400 μm and the oxide film 251 is formed to have a thickness of substantially 1.0 μm.

Next, as shown in FIG. 4B, the insulating film 51 which constitutes the surface layer of the vibration plate 50 at the side of the flow path formation substrate 10 and is made of zirconium oxide is formed on the oxide film 251. At this time, the oxide film 251 has been formed on the surface of the supporting substrate 250, thereby enhancing adhesiveness of the insulating film 51 to the supporting substrate 250. As described above, the vibration plate 50 is formed only by the insulating film 51 in the embodiment.

Next, as shown in FIG. 4C, the piezoelectric elements 300 and the lead electrodes 90 are sequentially formed on the insulating film 51 (vibration plate 50). At this time, the through-hole 51a which connects the communicating portion 15 and the reservoir portion 32 is formed on the insulating film 51. It is to be noted that since it is sufficient that the piezoelectric elements 300, the lead electrodes 90 and the like are formed by a commonly known technique, methods for forming the piezoelectric elements 300, the lead electrodes 90 and the like are not described in detail.

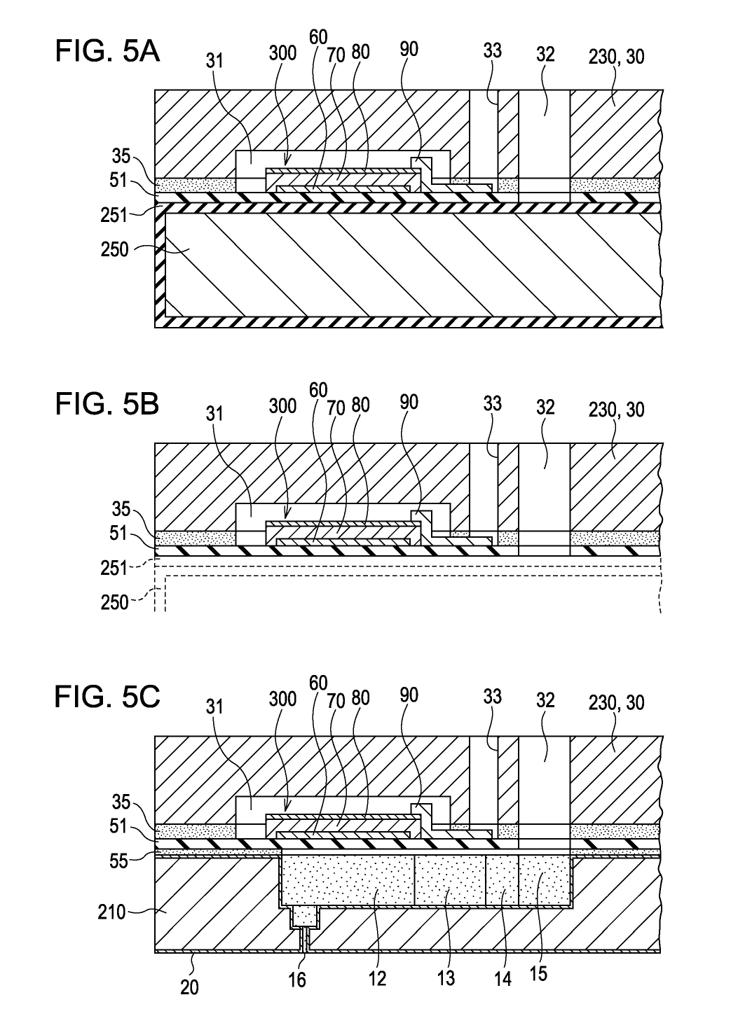

Next, as shown in FIG. 5A, a protection substrate wafer 230 on which a plurality of protection substrates 30 are integrally formed is bonded to the surface of the supporting substrate 250 at the side of the piezoelectric elements 300. In the embodiment, the supporting substrate 250 and the protection substrate wafer 230 are bonded to each other with a thermosetting adhesive 35, for example.

Next, as shown in FIG. 5B, a surface of the insulating film 51 is exposed by removing the supporting substrate 250 and the oxide film 251 from a surface opposite to the protection substrate wafer 230. A method for removing the supporting substrate 250 and the oxide film 251 is not particularly limited. For example, the supporting substrate 250 and the oxide film 251 may be removed by the following method.

At first, the supporting substrate 250 is removed by grinding to an extent so that the supporting substrate 250 is slightly left. Thereafter, the supporting substrate 250 is completely removed by etching with an etching solution such as fluoro-nitric acid, for example. Further, for example, the oxide film 251 is removed by etching with an etching solution such as hydrofluoric so as to expose a surface of the insulating film 51. With such method, the supporting substrate 250 and the oxide film 251 can be removed rapidly and desirably.

Next, as shown in FIG. 5C, the flow path formation substrate wafer 210 on which ink flow paths such as the pressure generation chambers 12 are formed and the protection substrate wafer 230 are bonded to each other with an adhesive 55. That is to say, the flow path formation substrate wafer 210 is bonded onto the surface of the insulating film 51, which has been exposed in the above process.

Thereafter, unnecessary portions of outer circumferential portions of the flow path formation substrate wafer 210 and the protection substrate wafer 230 are cut by dicing or the like so as to be removed. Then, the compliance substrate 40 is bonded onto the protection substrate wafer 230. Subsequently, the flow path formation substrate wafer 210 and the like are divided into one chip size as shown in FIG. 1, thereby manufacturing an ink jet recording head according to the embodiment.

By manufacturing the ink jet recording head with the above method, an ink jet recording head in which the wall surfaces of the ink flow paths such as the pressure generation chambers 12 formed on the flow path formation substrate 10 are formed by the insulating film 51 and the protection film 20 can be desirably manufactured.

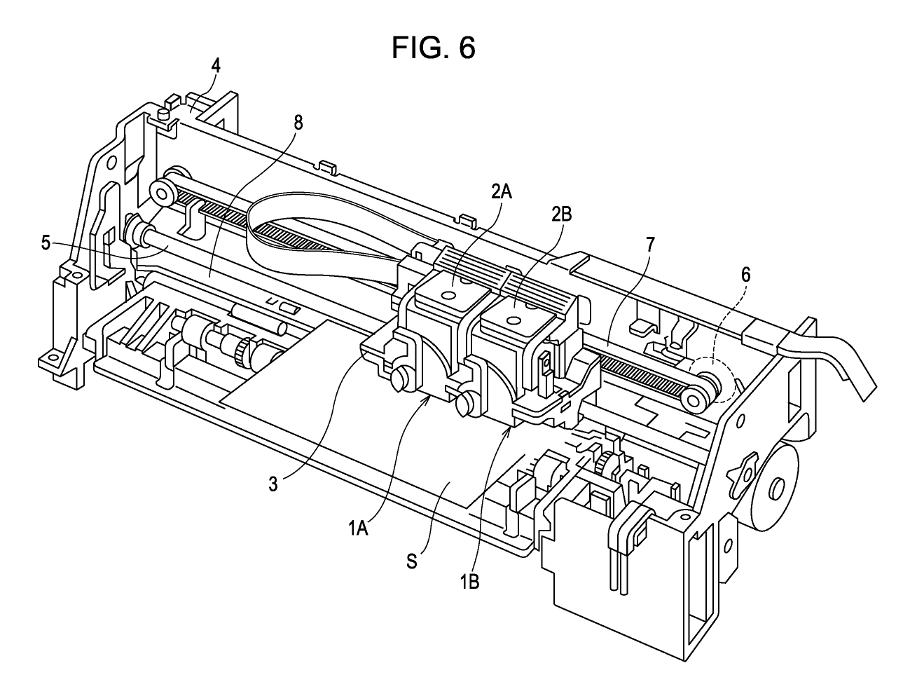

It is to be noted that such ink jet recording head constitutes a part of a recording head unit including flow paths communicating with ink cartridges and the like and is mounted on an ink jet recording apparatus (liquid ejecting apparatus). FIG. 6 is a schematic view illustrating an example of the ink jet recording apparatus.

As shown in FIG. 6, cartridges 2A and 2B constituting an ink supply unit are detachably provided on recording head units 1A and 1B each having the ink jet recording head. A carriage 3 on which the recording head units 1A and 1B are mounted is provided on a carriage shaft 5 attached to an apparatus main body 4 so as to be movable in a shaft direction. The recording head units 1A and 1B discharge, for example, a black ink composition and a color ink composition, respectively. A driving force of a driving motor 6 is transmitted to the carriage 3 through a plurality of gears (not shown) and a timing belt 7 so that the carriage 3 on which the recording head units 1A and 1B are mounted is moved along the carriage shaft 5. On the other hand, a platen 8 is provided on an apparatus main body 4 along the carriage 3. The platen 8 is rotatable with a driving force of a sheet feeding motor (not shown). A recording sheet S as a recording medium, such as a sheet fed by a sheet feeding roller and the like is transported while being wound over the platen 8.

Hereinbefore, an embodiment of the invention has been described. However, the invention is not limited to the embodiment and various changes can be added within a range without departing from the scope of the invention.

For example, in the embodiment, a protection film made of tantalum oxide is provided on the wall surfaces of the ink flow paths formed on a flow path formation substrate. However, it is needless to say that the same protection film may be provided on a wall surface of the reservoir portion formed on the protection substrate. This makes it possible to reliably suppress an ejection characteristic of ink droplets from being changed.

In addition, in the above embodiment, the ink jet recording head has been described as an example of a liquid ejecting head. However, the invention is widely aimed at liquid ejecting heads in general and can be applied to liquid ejecting heads which eject liquid droplets other than ink. As other liquid ejecting heads, various types of recording heads used for image recording apparatuses such as a printer, color material ejecting heads used for manufacturing a color filter such as a liquid crystal display, electrode material ejecting heads used for forming electrodes such as an organic EL display or a field emission display (FED), bioorganic compound ejecting heads used for manufacturing a bio chip, and the like are exemplified.

1. A liquid ejecting head comprising:
a flow path formation substrate on which liquid flow paths including nozzles for ejecting liquid droplets and pressure generation chambers communicating with the nozzles are formed;
a vibration plate which is provided on the flow path formation substrate and constitutes one side surfaces of the pressure generation chambers; and
piezoelectric elements which are provided on the vibration plate and each of which corresponds to each of the pressure generation chambers,
wherein an surface layer of the vibration plate at the side of the flow path formation substrate is formed by an insulating film made of zirconium oxide, and
a protection film made of a material which is resistant to liquid is provided on a surface of the flow path formation substrate so as to cover wall surfaces of the liquid flow paths.

2. The liquid ejecting head according to claim 1,
wherein the protection film is made of tantalum oxide.

3. The liquid ejecting head according to claim 1,
wherein the flow path formation substrate is made of a silicon substrate.

4. A liquid ejecting apparatus comprising the liquid ejecting head according to claim 1.

5. A method for manufacturing a liquid ejecting head which includes a flow path formation substrate on which liquid flow paths including nozzles for ejecting liquid droplets and pressure generation chambers communicating with the nozzles are formed, a vibration plate which is provided on the flow path formation substrate and constitutes one side surfaces of the pressure generation chambers, and piezoelectric elements which are provided on the vibration plate and each of which corresponds to each of the pressure generation chambers, the method comprising:
forming a protection film made of a material which is resistant to liquid on a surface of the flow path formation substrate on which the liquid flow paths are formed so as to cover wall surfaces of the liquid flow paths;
forming an oxide film made of silicon dioxide by thermally oxidizing a surface of a supporting substrate made of a silicon substrate;
forming the vibration plate including at least an insulating film made of zirconium oxide on the oxide film;
forming the piezoelectric elements on the vibration plate;
exposing a surface of the insulating film by removing the supporting substrate and the oxide film from a surface opposite to the piezoelectric elements; and
bonding the insulating film constituting the vibration plate and the flow path formation substrate on which the protection film is formed to each other.
